(19) United States
(12) Patent Application Publication
(10) Pub. No.: US 2024/0166944 A1
(43) Pub. Date: May 23, 2024

(54) QUANTUM DOT, METHOD FOR PREPARING QUANTUM DOT, AND DISPLAY DEVICE INCLUDING QUANTUM DOT

(71) Applicant: Samsung Display Co., Ltd., Yongin-si (KR)

(72) Inventors: SUNGJAE KIM, Yongin-si (KR); Youngsik KIM, Yongin-si (KR); SEUNG-WON PARK, Yongin-si (KR); Bitna YOON, Yongin-si (KR); DONGHEE LEE, Yongin-si (KR); JUNEHYUK JUNG, Yongin-si (KR)

(73) Assignee: Samsung Display Co., Ltd., Yongin-si (KR)

(21) Appl. No.: 18/446,629

(22) Filed: Aug. 9, 2023

(30) Foreign Application Priority Data
Nov. 22, 2022 (KR) 10-2022-0157104

(51) Int. Cl. C09K 11/62; C09K 11/64; G02F 1/01

(52) U.S. Cl. CPC C09K 11/621; C09K 11/64; G02F 1/01; H10K 50/115

(57) ABSTRACT

Embodiments provide a quantum dot, a method of preparing the quantum dot, and a display device including the quantum dot. The quantum dot includes a core including zinc (Zn), tin (Sn), and phosphorous (P), and a shell surrounding the core, wherein a molar ratio of the number of moles of zinc to a number of moles of tin is in a range of about 0.1 to about 0.2.

### CROSS-REFERENCE TO RELATED APPLICATION(S)

This application claims priority to and benefits of Korean Patent Application No. 10-2022-0157104 under 35 U.S.C. § 119, filed on Nov. 22, 2022 in the Korean Intellectual Property Office, the entire contents of which are incorporated herein by reference.

### BACKGROUND

### 1. Technical Field

The disclosure relates to a quantum dot, a method for manufacturing the quantum dot, and a display device including the quantum dot.

### 2. Description of the Related Art

Various types of display devices used for multimedia devices such as a television set, a mobile phone, a tablet computer, a navigation system, and a game console are being developed. Such display devices include a display module including a so-called self-luminescent display element configured to display by causing a light emitting material to emit light.

Such display devices may include different types of light control layers depending on pixels to enhance color reproducibility. The light control layer may transmit only light source light in a certain wavelength range or convert the wavelength range of the light source light. The development of light emitting elements using quantum dots as a light emitting material has been underway, and there is a demand for an increase in the light emitting efficiency and better high color properties as for the light emitting elements using quantum dots.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a quantum dot exhibiting high quantum yield and excellent stability.

The disclosure also provides a method for preparing a quantum dot exhibiting high quantum yield and excellent stability.

The disclosure also provides a display device including a quantum dot containing a shell doped with a Group IIIA oxide, thus improving light emitting efficiency.

An embodiment provides a quantum dot which may include a core containing silver, indium, gallium, and sulfur, and a shell surrounding the core, the shell including a Group III-VI compound, wherein the shell may be doped with a Group IIIA oxide.

In an embodiment, the Group III-VI compound may be GaS.

In an embodiment, the shell may include a first shell surrounding the core, and a second shell surrounding the first shell; the first shell and the second shell may each include the Group III-VI compound; and at least one of the first shell or the second shell may be doped with the Group IIIA oxide.

In an embodiment, the second shell may be doped with the Group IIIA oxide.

In an embodiment, the first shell may include GaS, and the second shell may include the GaS and the Group IIIA oxide.

In an embodiment, the Group IIIA oxide may include aluminum oxide.

In an embodiment, a molar ratio of the Group IIIA element of the Group IIIA oxide included in the quantum dot to sulfur included in the quantum dot may be in a range of about 0.001 to about 0.25.

In an embodiment, the shell layer may have a thickness in a range of about 0.01 nm to about 10 nm.

In an embodiment, the Group IIIA oxide may be disposed on a surface of the shell.

In an embodiment, the quantum dot may have a central emission wavelength in a range of about 510 nm to about 540 nm.

An embodiment provides a method for preparing a quantum dot which may include providing a core including silver, indium, gallium, and sulfur; forming a first shell surrounding the core and including a Group III-VI compound; and reacting a surface of the first shell with a Group IIIA oxide.

In an embodiment, the forming of the first shell may include reacting the core with a Group III precursor and a Group VI precursor.

In an embodiment, the method may further include reacting the surface of the first shell with a Group III precursor and a Group VI precursor, wherein the step of reacting the surface of the first shell with the Group IIIA oxide and the step of reacting the surface of the first shell with the Group III precursor and the Group VI precursor may be performed in a same process.

In an embodiment, the surface of the first shell may react with the Group IIIA oxide, the Group III precursor, and the Group VI precursor to form a second shell surrounding the first shell.

In an embodiment, the Group IIIA oxide may be represented by Formula 1 or Formula 2:

M(OR)₃ [Formula 1]

M(OR)₃₋ₙ(SR′)ₙ [Formula 2]

In Formulas 1 and 2, M may be aluminum, indium, or thallium; R and R′ may each independently be a substituted or unsubstituted alkyl group having 1 to 20 carbon atoms; and n may be an integer from 0 to 3.

In an embodiment, the Group IIIA oxide may be aluminum isopropoxide.

In an embodiment, the method may further include surface-treating the surface of the first shell with a first solvent, before the step of reacting the surface of the first shell with the Group IIIA oxide.

An embodiment provides a display device which may include a display panel, and a light conversion layer disposed on the display panel and including light control units, wherein at least one of the light control units may include a quantum dot that includes a core containing silver, indium, gallium, and sulfur, and a shell surrounding the core, the shell containing a Group III-VI compound, and the shell may be doped with a Group IIIA oxide.

In an embodiment, the display panel may include a light emitting element generating a first light, and the light conversion layer may include a first light control unit transmitting the first light, a second light control unit converting the first light into a second light, and a third light control unit converting the first light into a third light.

In an embodiment, the shell may include a first shell surrounding the core, and a second shell surrounding the core, the first shell and the second shell may each include the Group III-VI compound, and at least one of the first shell or the second shell may be doped with the Group IIIA oxide.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of an electronic device according to an embodiment;

FIG. 2 is an exploded schematic perspective view of an electronic device according to an embodiment;

FIG. 3 is a schematic cross-sectional view of a display device according to an embodiment, which corresponds to line I-I′ of FIG. 1;

FIG. 4 is a schematic cross-sectional view of a light emitting element according to an embodiment;

FIG. 5 is a schematic cross-sectional view of a structure of a quantum dot according to an embodiment;

FIG. 6 is an enlarged schematic plan view of a portion of a display device according to an embodiment;

FIG. 7 is a schematic cross-sectional view of a display device according to an embodiment;

FIG. 8 is a schematic cross-sectional view of a display device according to another embodiment;

FIG. 9 is a flowchart showing a method for preparing a quantum dot according to an embodiment; and

FIG. 10 is a schematic view of a process in a method for preparing a quantum dot according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

As used herein, the term “disposed directly on” may be interpreted such that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

As used herein, the term “Group” refers to a Group in the IUPAC periodic table of elements.

As used herein, the term “Group III” may include Group IIIA elements and Group IIIB elements. Examples of Group III elements may include aluminum (Al), indium (In), gallium (Ga), or titanium (Ti), but are not limited thereto.

As used herein, the term “Group VI” may include Group VIA elements and Group VIB elements. Examples of Group VI elements may include oxygen (O), sulfur (S), selenium (Se), or tellurium (Te), but are not limited thereto.

Hereinafter, a quantum dot, a light emitting element, and a display device including the same according to an embodiment will be described with reference to the accompanying drawings.

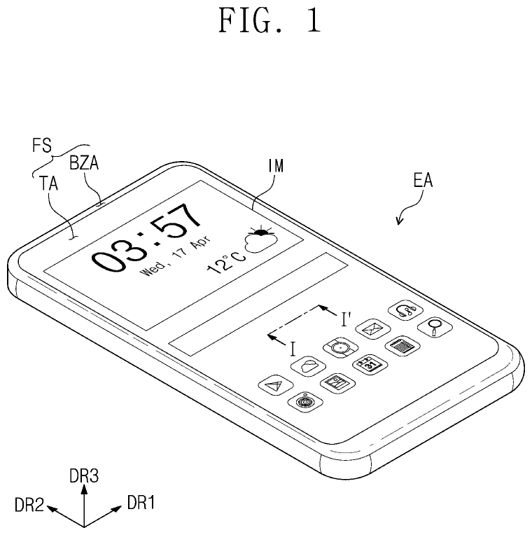

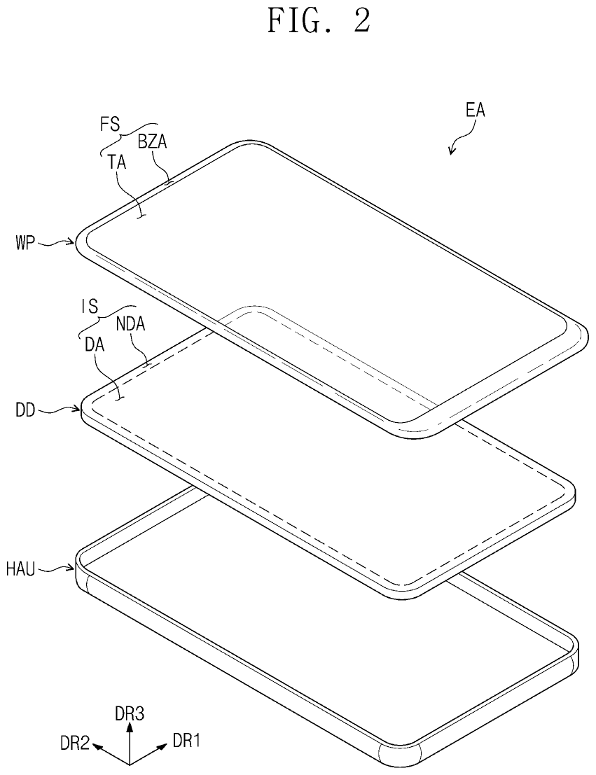

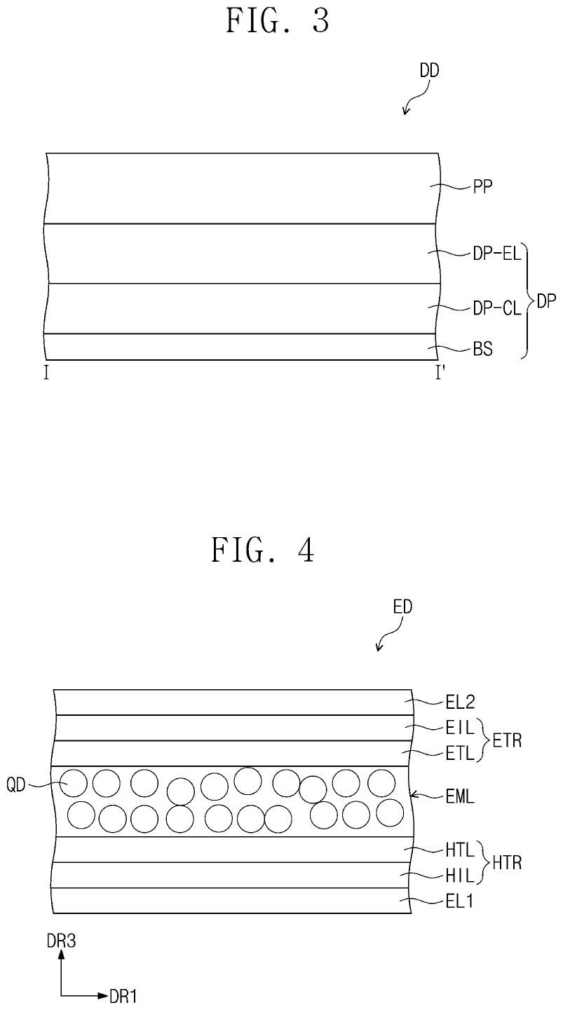

FIG. 1 is a schematic perspective view illustrating an electronic device EA according to an embodiment. FIG. 2 is an exploded schematic perspective view of the electronic device EA according to an embodiment. FIG. 3 is a schematic cross-sectional view of a display device DD according to an embodiment, which corresponds to line I-I′ of FIG. 1. FIG. 4 is a schematic cross-sectional view of a light emitting element ED according to an embodiment.

In an embodiment, an electronic device EA may be a large-sized electronic device such as a television set, a monitor, or an outdoor billboard. In another embodiment, the electronic device EA may be a small-sized or a medium-sized electronic device such as a personal computer, a laptop computer, a personal digital terminal, a car navigation unit, a game console, a smartphone, a tablet, and a camera. These devices are merely provided as embodiments, and other electronic devices may be employed. As an example, a smartphone may be shown as an embodiment of the electronic device EA.

The electronic device EA may include a display device DD and a housing HAU. The display device DD may display an image IM through a display surface IS, and a user may view images provided through a transmission region TA corresponding to a front surface FS of the electronic device EA. The image IM may include still images as well as dynamic images. FIG. 1 shows that the front surface FS is parallel to a plane defined by a first direction DR1 and a second direction DR2 crossing the first direction DR1. However, this is merely an example, and the front surface FS of the electronic device EA in another embodiment may have a curved shape.

Among the normal directions of the front surface FS of the electronic device EA, for example, a thickness direction of the electronic device EA, a direction in which the image IM is displayed is indicated by a third direction DR3. A front surface (or an upper surface) and a rear surface (or a lower surface) of respective members may be defined by the third direction DR3.

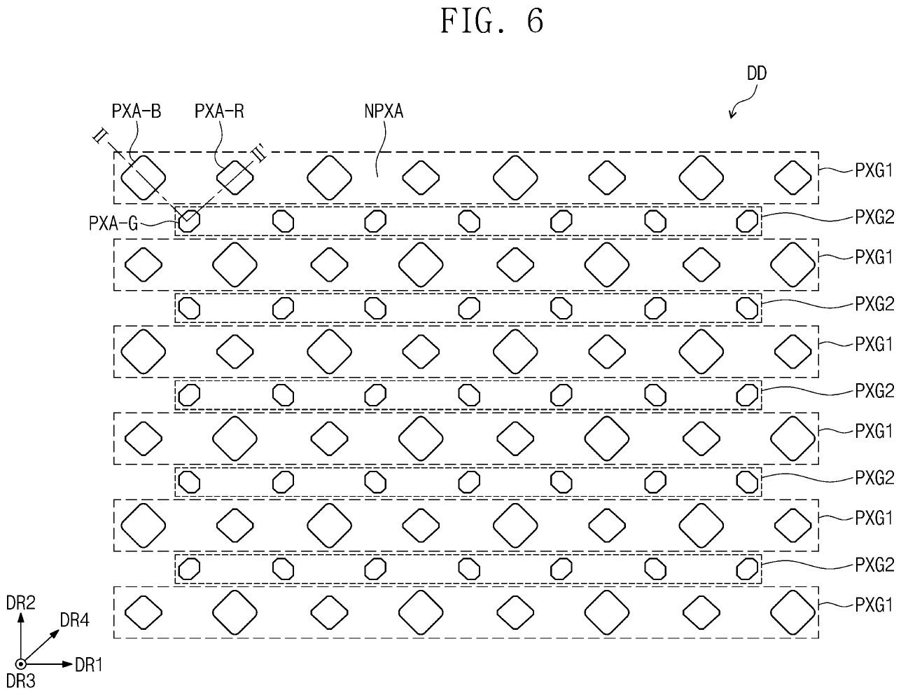

A fourth direction DR4 (see FIG. 6) may be a direction between the first direction DR1 and the second direction DR2. The fourth direction DR4 may be positioned on a plane parallel to the plane defined by the first direction DR1 and the second direction DR2. The directions indicated by the first to fourth directions DR1, DR2, DR3, and DR4 are relative concepts, and may thus be changed to other directions.

Although not illustrated in the drawing, the electronic device EA may include a foldable display device having a folding area and a non-folding area, or a bending display device having at least one bending portion.

The electronic device EA may include a display device DD and a housing HAU. The front surface FS in the electronic device EA may correspond to a front surface of the display device DD and may correspond to a front surface of a window WP. Accordingly, like reference characters will be given for the front surface of the electronic device EA, the front surface of the display device DD, and the front surface of the window WP.

The housing HAU may accommodate the display device DD. The housing HAU may be disposed to cover the display device DD while exposing the display surface IS which is a top surface of the display device DD. The housing HAU may cover side surfaces and a bottom surface of the display device DD, and may expose the entire top surface. However, embodiments are not limited thereto, and the housing HAU may cover a portion of the top surface as well as the side surfaces and the bottom surface of the display device DD.

In the electronic device EA according to an embodiment, the window WP may include an optically transparent insulating material. The window WP may include a transmission region TA and a bezel region BZA. A front surface FS of the window WP including the transmission region TA and the bezel region BZA corresponds to a front surface FS of the electronic device EA.

In FIGS. 1 and 2, the transmission region TA is shown in a rectangular shape with rounded corners. However, this is presented as an example, and the transmission region TA may have various shapes and is not limited to any one embodiment.

The transmission region TA may be an optically transparent region. The bezel region BZA may be a region having a relatively lower light transmittance than the transmission region TA. The bezel region BZA may have a color (e.g., a predetermined or a selectable color). The bezel region BZA may be adjacent to the transmission region TA and may surround the transmission region TA. The bezel region BZA may define the shape of the transmission region TA. However, embodiments are not limited to what is shown, and the bezel region BA may be disposed adjacent to only one side of the transmission region TA, and a portion thereof may be omitted.

The display device DD may be disposed below the window WP. As used herein, “below” may indicate a direction opposite to the direction in which the display device DD provides an image.

In an embodiment, the display device DD may be configured to generate an image IM. The image IM generated in the display device DD may be displayed on the display surface IS, and may be viewed by users through the transmission region TA from the outside. The display device DD includes a display region DA and a non-display region NDA. The display region DA may be a region activated according to electrical signals. The non-display region NDA may be a region covered by the bezel region BZA. The non-display region NDA may be adjacent to the display region DA. The non-display region NDA may surround the display region DA.

Referring to FIG. 3, the display device DD may include a display panel DP and a light control layer PP disposed on the display panel DP. The display panel DP may include a display element layer DP-EL. The display element layer DP-EL may include a light emitting element ED.

The light control layer PP may be disposed on the display panel DP to control light that is reflected at the display panel DP from an external light. The light control layer PP may include, for example, a polarizing layer or a color filter layer.

In the display device DD according to an embodiment, the display panel DP may be a light emitting display panel. For example, the display panel DP may be a quantum dot light emitting display panel including a quantum dot light emitting element. However, embodiments are not limited thereto.

The display panel DP may include a base substrate BS, a circuit layer DP-CL disposed on the base substrate BS, and a display element layer DP-EL disposed on the circuit layer DP-CL.

The base substrate BS may provide a base surface on which the display element layer DP-EL is disposed. The base substrate BS may be a glass substrate, a metal substrate, a plastic substrate, and the like. However, embodiments are not limited thereto, and the base substrate BS may include an inorganic layer, an organic layer, or a composite material layer. The base substrate BS may be a flexible substrate that may be readily bent or folded.

In an embodiment, the circuit layer DP-CL may be disposed on the base substrate BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting element ED of the display element layer DP-EL.

FIG. 4 is a schematic cross-sectional view of a light emitting element ED according to an embodiment. Referring to FIG. 4, the light emitting element according to an embodiment includes a first electrode EL1, a second electrode EL2 facing the first electrode EL1, and functional layers disposed between the first electrode EL1 and the second electrode EL2 and having an emission layer EML.

The functional layers may include a hole transport region HTR disposed between the first electrode EL1 and the emission layer EML, and an electron transport region ETR disposed between the second electrode EL2 and the emission layer EML. Although not shown in the drawings, in an embodiment, a capping layer may be further disposed on the second electrode EL2.

Each of the hole transport region HTR and the electron transport region ETR may include sub-functional layers. For example, the hole transport region HTR may include a hole injection layer HIL and a hole transport layer HTL as a sub-functional layer, and the electron transport region ETR may include an electron injection layer EIL and an electron transport layer ETL as a sub-functional layer. However, embodiments are not limited thereto, and the hole transport region HTR may further include an electron blocking layer (not shown) as a sub-functional layer, and the electron transport region ETR may further include a hole blocking layer (not shown) as a sub-functional layer.

In the light emitting element ED according to an embodiment, the first electrode EL1 may have conductivity. The first electrode EL1 may be formed of a metal alloy or a conductive compound. The first electrode EL1 may be an anode. The first electrode EL1 may be a pixel electrode.

In the light emitting element ED according to an embodiment, the first electrode EL1 may be a reflective electrode. However, embodiments are not limited thereto. For example, the first electrode EL1 may be a transmissive electrode or a transflective electrode. When the first electrode EL1 is a transflective electrode or a reflective electrode, the first electrode EL1 may include Ag, Mg. Cu, Al, Pt. Pd, Au, Ni, Nd, Ir, Cr, Li, Ca, LiF/Ca, LiF/Al, Mo, Ti, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and the like. For example, the first electrode EL1 may be a multilayer metal film and may have a structure in which metal films of ITO/Ag/ITO are stacked.

The hole transport region HTR may be provided on the first electrode EL1. The hole transport region HTR may include a hole injection layer HIL, a hole transport layer HTL, and the like. The hole transport region HTR may further include at least one of a hole buffer layer (not shown) or an electron blocking layer (not shown), in addition to the hole injection layer HIL and the hole transport layer HTL. The hole buffer layer (not shown) may compensate for a resonance distance according to the wavelength of light emitted from an emission layer EML, and may thus increase luminous efficiency. Materials that may be included in the hole transport region HTR may be used as materials included in the hole buffer layer (not shown). The electron blocking layer (not shown) may prevent electrons from being injected from the electron transport region ETR to the hole transport region HTR.

The hole transport region HTR may be a layer consisting of a single material, a layer including different materials, or a structure including multiple layers including different materials. For example, the hole transport region HTR may be a structure including different materials, or may be a structure in which a hole injection layer HIL/hole transport layer HTL, a hole injection layer HIL/hole transport layer HTL/hole buffer layer (not shown), a hole injection layer HIL/hole buffer layer (not shown), a hole transport layer HTL/hole buffer layer (not shown), or a hole injection layer HIL/hole transport layer HTL/electron blocking layer (not shown) are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL, for example, may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS). polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), and the like.

The hole transport layer HTL may include a material of the related art. For example, the hole transport layer HTL may further include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4 -diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and the like.

The hole transport region HTR may have a thickness in a range of about 5 nm to about 1,500 nm. For example, the hole transport region HTR may have a thickness in a range of about 10 nm to about 500 nm. The hole injection layer HIL, for example, may have a thickness in a range of about 3 nm to about 100 nm, and the hole transport layer HTL may have a thickness in a range of about 3 nm to about 100 nm. For example, an electron blocking layer (not shown) may have a thickness in a range of about 1 nm to about 100 nm. When the thicknesses of the hole transport region HTR, the hole injection layer HIL, the hole transport layer HTL, and the electron blocking layer (not shown) satisfy the above-described ranges, satisfactory hole transport properties may be obtained without a substantial increase in driving voltage.

The emission layer EML may be provided on the hole transport region HTR. The emission layer EML may include quantum dots QD.

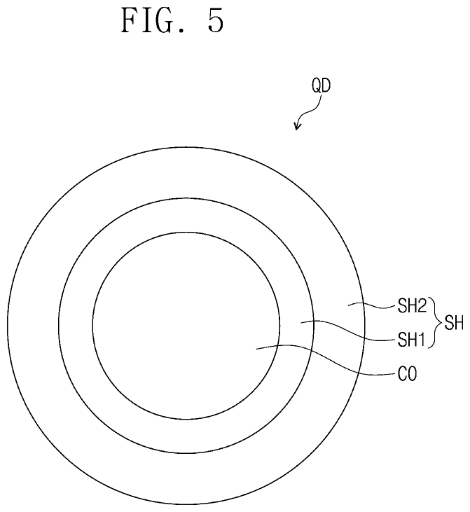

The quantum dots QD included in the emission layer EML may form a layer. In FIG. 4, as an example, the quantum dots QD having a circular cross-section may be arranged to form two layers, but embodiments are not limited thereto. For example, according to the thickness of the emission layer EML, the shape of the quantum dots QD included in the emission layer EML, the average diameter of the quantum dots QD, and the like, the arrangement of the quantum dots QD may vary. For example, in the emission layer EML, the quantum dots QD may be arranged adjacent to each other to form a single layer, or may form multiple layers such as two or three layers. The quantum dots QD according to an embodiment will be described in detail with reference to FIG. 5.

In the light emitting element ED according to an embodiment, the emission layer EML may include a host and a dopant. In an embodiment, the emission layer EML may include the quantum dots QD as a dopant material. In an embodiment, the emission layer EML may further include a host material.

In the light emitting element ED according to an embodiment, the emission layer EML may emit fluorescence. For example, the quantum dots QD may be used as a fluorescent dopant material.

In the light emitting element ED according to an embodiment, the electron transport region ETR may be provided on the emission layer EML. The electron transport region ETR may include at least one of a hole blocking layer (not shown), an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may be a single layer structure consisting of an electron injection layer EIL or an electron transport layer ETL, or may have a structure including an electron injection material and an electron transport material. The electron transport region ETR may be a single layer structure including different materials, or may have a structure in which an electron transport layer ETL/electron injection layer EIL, or a hole blocking layer (not shown)/electron transport layer ETL/electron injection layer EIL are stacked in its respective stated order from the emission layer EML, but embodiments are not limited thereto. The electron transport region ETR may have a thickness in a range of, for example, about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

When the electron transport region ETR includes the electron transport layer ETL, the electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), or a mixture thereof. The electron transport layers ETL may have a thickness in a range of about 10 nm to about 100 nm. For example, the electron transport layer ETL may have a thickness in a range of about 15 nm to about 50 nm. When the thickness of the electron transport layers ETL satisfies the above-described range, satisfactory electron transport properties may be obtained without a substantial increase in driving voltage.

When the electron transport region ETR includes an electron injection layer EIL, the electron transport region ETR may include: a halogenated metal such as LiF, NaCl, CsF, RbCl, and RbI; a lanthanide metal such as Yb; a metal oxide such as LizO and BaO; or lithium quinolate (LiQ), and the like, but embodiments are limited thereto. The electron injection layers EIL may also be formed of a mixture material of an electron transport material and an insulating organometallic salt. For example, the organometallic salt may include metal acetates, metal benzoates, metal acetoacetates, metal acetylacetonates, or metal stearates. The electron injection layer EIL may have a thickness in a range of about 0.1 nm to about 10 nm. For example, the electron injection layer EIL may have a thickness in a range of about 0.3 nm to about 9 nm. When the thickness of the electron injection layers EIL satisfies the above-described range, satisfactory electron injection properties may be obtained without a substantial increase in driving voltage.

As described above, the electron transport region ETR may include a hole blocking layer (not shown). The hole blocking layer (not shown) may include, for example, at least one of 2,9-dimethyl-4,7-diphenyl-1,10-phenanthroline (BCP) or 4,7-diphenyl-1,10-phenanthroline (Bphen), but embodiments are not limited thereto.

The second electrode EL2 may be provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and the like.

When the second electrode EL2 is the transflective electrode or the reflective electrode, the second electrode EL2 may include Ag, Mg, Cu, Al, Pt. Pd, Au, Ni, Nd, Ir, Cr, Li, Ca, LiF/Ca, LiF/Al, Mo, Ti, Yb, a compound thereof (c.g., AgYb, a compound of AgMg and MgAg, and the like depending on the amount), or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and the like.

Although not shown in the drawings, the second electrode EL2 may be electrically connected to an auxiliary electrode. When the second electrode EL2 is electrically connected to the auxiliary electrode, the resistance of the second electrode EL2 may decrease.

FIG. 5 is a schematic cross-sectional view of a structure of a quantum dot according to an embodiment.

Referring to FIG. 5, the quantum dots QD may include a core CO and a shell SH surrounding the core CO.

The core CO may include Group I-III-VI compounds. The core CO may be a semiconductor compound having a chalcopyrite structure. The core CO may be a Group I-III-VI quaternary AgInGaS compound. The core CO may include silver (Ag), indium (In), gallium (Ga), and sulfur (S). The core CO may be formed of silver, indium, gallium, and sulfur. The quantum dots QD according to an embodiment may include the core CO containing Group I-III-VI compounds, and may thus have a high blue light absorption rate.

In an embodiment, the quantum dots QD may be non-Cd-based quantum dots. For example, the quantum dots QD may not include cadmium (Cd).

The core CO including silver, indium, gallium, and sulfur may have an absorption wavelength in a range of about 350 nm to about 530 nm. Accordingly, the core CO may absorb blue light in the wavelength ranges described above to emit green light or red light. The emission wavelength of light emitted from the quantum dots QD may be controlled by regulating the size of the core CO, the thickness of the shell SH, and the like.

In an embodiment, the quantum dots QD may emit light having an emission wavelength in a range of about 510 nm to about 540 nm. For example, the quantum dots QD may emit green light having an emission wavelength in a range of about 510 nm to about 540 nm. However, embodiments are not limited thereto, and the quantum dots QD may emit light having an emission wavelength in a range of about 630 nm to about 680 nm. For example, the quantum dots QD may emit red light having an emission wavelength in a range of about 630 nm to about 680 nm. The quantum dots QD regulate an amount of elements included in the core CO, and may thus emit light having a desired emission wavelength. For example, the emission wavelength of light emitted from the quantum dots QD may be controlled by regulating the amount of silver, indium, gallium, and sulfur included in the core CO.

The shell SH may surround the core CO. The shell SH may cover an entire surface of the core CO. The shell SH may include Group III-VI compounds and a Group IIIA oxide. The shell SH may include Group III-VI compounds. In an embodiment, the Group III-VI compounds may include GaS. The shell SH may include GaS.

The core CO and the shell SH may be formed independently and separately. Accordingly, a border may be defined between the core CO and the shell SH. For example, the core CO and the shell SH may be distinguishable.

In an embodiment, the shell SH may be doped with a Group IIIA oxide. For example, the Group III-VI compounds included in the shell SH may be doped with the Group IIIA oxide. The shell SH may be doped with an oxide of aluminum, indium, or thallium. For example, the shell SH may be doped with aluminum oxide. As used herein, the phrase “α is doped with β” indicate that at least one cation included in α is substituted with a cation included in β through cation exchange method. In the quantum dots according to an embodiment, the shell SH may include Group III-VI compounds, and at least one of the Group III elements of the Group III-VI compounds may be substituted with a Group IIIA element of the Group IIIA oxide. For example, when the shell SH includes GaS and is doped with aluminum oxide, at least one of Ga elements included in the shell SH may be substituted with an Al element of aluminum oxide.

In the quantum dots QD according to an embodiment, the Group IIIA oxide present in the shell SH may have a greater concentration toward the surface of the shell SH in terms of concentration gradient. In an embodiment, the Group IIIA oxide may be placed on the surface of the shell SH. The shell SH of the quantum dots QD may include a first portion adjacent to the core CO and a second portion adjacent to the surface of the shell SH. The Group IIIA oxide in the second portion of the shell SH may have a greater concentration than the Group IIIA oxide in the first portion of the shell SH. However, embodiments are not limited thereto, and the Group IIIA oxide may have discontinuous concentration changes within the shell SH, or may be present at a uniform concentration within the shell SH.

As the quantum dots QD according to an embodiment include the shell SH doped with the Group IIIA oxide, a passivation effect for the core CO may be excellent. Accordingly, the quantum dots QD according to an embodiment may exhibit high quantum yield properties.

The shell SH may include a first shell SH1 adjacent to the core CO and a second shell SH2 spaced apart from the core CO. The second shell SH2 may be spaced apart from the core CO with the first shell SH1 therebetween. The first shell SH1 may surround the core CO, and the second shell SH2 may surround the first shell SH1.

The second shell SH2 may completely cover the first shell SH1. Accordingly, the surface of the quantum dots QD may be defined by an outer surface of the second shell SH2. Covered by the second shell SH2, the first shell SH1 may not be exposed.

The first shell SH1 may include Group III-VI compounds. The first shell SH1 may be formed of Group III-VI compounds. In an embodiment, the first shell SH1 may include GaS. For example, the first shell SH1 may be formed of GaS.

The second shell SH2 may include Group III-VI compounds and a Group IIIA oxide. The second shell SH2 may be doped with the Group IIIA oxide. For example, the second shell SH2 may be doped with an oxide of Group IIIA elements such as aluminum, indium, or thallium. In an embodiment, the second shell SH2 may be doped with an aluminum oxide.

The second shell SH2 may include Group III-VI compounds, and at least one of the Group III elements of the Group III-VI compounds may be substituted with a Group IIIA clement of a Group IIIA oxide. For example, when the second shell SH2 includes GaS and is doped with an aluminum oxide, at least one of the Ga elements included in the second shell SH2 may be substituted with an Al element of an aluminum oxide.

In an embodiment, the Group III-VI compound included in the first shell SH1 and the second shell SH2 may be the same. However, embodiments are not limited thereto, and the Group III-VI compounds included in the first shell SH1 and the second shell SH2 may be different.

The quantum dots QD according to an embodiment may include the second shell SH2 surrounding the first shell SH1, and may thus have both greater quantum yield and greater quantum yield retention. The first shell SH1 including GaS may have an amorphous structure, and accordingly, stability may be reduced. Accordingly, in quantum dots including only the core CO and the first shell SH1, the quantum yield may decrease due to the denaturation of the first shell SH1. According to embodiments, as the quantum dots QD include the second shell SH2 surrounding the first shell SH1, and the second shell SH2 includes a structure doped with Group IIIA oxide, a passivation effect for the core CO may be excellent. Accordingly, the quantum dots QD according to an embodiment may exhibit excellent stability to provide high quantum yield and high quantum yield retention.

In an embodiment, a ratio of the number of atoms of the Group IIIA element included in the quantum dots QD to the number of anions included in the quantum dots QD may be in a range of about 0.001 to about 0.25. For example, in the quantum dots QD, a ratio of the number of atoms of the Group IIIA elements included in the shell SH to a sum of sulfur elements included in the core CO and Group VI elements included in the shell SH may be in a range of about 0.001 to about 0.25. For example, when the core CO includes AgInGaS and the shell SH includes GaS and aluminum oxide, an amount of aluminum (Al) included in the shell SH relative to sulfur included in the quantum dots QD may be in a range of about 0.1 atomic % to about 25 atomic %. However, embodiments are not limited thereto. The amount of elements included in the quantum dots QD may be measured through inductively coupled plasma atomic emission spectroscopy (ICP-AES), but embodiments are not limited thereto.

In an embodiment, a ratio of the number of atoms of the Group IIIA elements to the number of anions included in the quantum dots QD may be represented by Formula A:

N₁/(N₂+N₃) [Formula A]

In Formula A, N₁ may be the number of Group IIIA elements included in the shell SH, N₂ may be the number of sulfur atoms included in the core CO, and N₃ may be the number of Group VI elements included in the shell SH. When the shell SH includes the first shell SH1 and the second shell SH2, N₃ may be a sum of the number of Group VI elements included in the first shell SH1 and the number of Group VI elements included in the second shell SH2.

Although FIG. 5 shows that an interface is defined between the first shell SH1 and the second shell SH2, embodiments are not limited thereto. When the shell SH includes the first shell SH1 and the second shell SH2, and the first shell SH1 and the second shell SH2 include a same Group III-VI compound, there may not be a border defined between the first shell SH1 and the second shell SH2. For example, the first shell SH1 and the second shell SH2 may be indistinguishable. However, embodiments are not limited thereto. For example, when the first shell SH1 and the second shell SH2 include different Group III-VI compounds, as shown in FIG. 5, there may be a border defined between the first shell SH1 and the second shell SH2.

In an embodiment, the quantum dots QD may have a particle diameter in a range of about 2 nm to about 20 nm. When the quantum dots QD satisfy the average particle diameter ranges described above, a characteristic behavior as quantum dots QD and excellent dispersibility as well may be achieved. When the average particle diameter of the quantum dots QD is variously selected within the range as described above, the emission wavelength of the quantum dots QD and/or the semiconductor properties of the quantum dots may be variously changed.

The form of the quantum dots QD is not limited as long as it is a form used in the related art, For example, quantum dots may have shapes such as a spherical shape, a pyramidal shape, a multi-arm shape, or a cubic shape, or quantum dots may be in the form of nanoparticles, nanotubes, nanowires, nanofibers, nanoplatelets, and the like. In an embodiment, the quantum dots QD may be spherical.

The quantum dots QD may emit green light. The quantum dots QD may have a central emission wavelength in a range of about 510 nm to about 540 nm. For example, quantum dots QD may emit light having a maximum emission wavelength in a range of about 510 nm to about 540 nm. However, embodiments are not limited thereto, and the quantum dots QD may emit red light. For example, the quantum dots QD may have a central emission wavelength in a range of about 630 nm to about 680 nm. For example, the quantum dots QD may emit light having a maximum emission wavelength in a range of about 630 nm to about 680 nm.

In an embodiment, the quantum dots QD may have a full width at half maximum (FWHM) of an emission wavelength spectrum equal to or less than about 50 nm. For example, the quantum dots QD may have a full width at half maximum of an emission wavelength spectrum equal to or less than about 40 nm. When the full width at half maximum of the quantum dots QD satisfies the ranges described above, color purity and color reproducibility of the quantum dots QD may be improved. Light emitted through the quantum dots QD may be emitted in all directions, so that a wide viewing angle may be improved.

Although not shown in the drawings, the quantum dots QD may further include a ligand chemically bonded to a surface. The ligand may be chemically bonded to the surface of the quantum dots QD to passivate the quantum dots QD. For example, the quantum dots QD may further include a ligand chemically bonded to the second shell SH2. In an embodiment, the ligand may include an organic ligand or a metal halide.

The quantum dots QD according to an embodiment include the shell SH doped with the Group IIIA oxide, and may thus exhibit improved reliability. A substantial portion of the Group IIIA oxide may be disposed in a surface of the quantum dots QD according to an embodiment, and the Group IIIA oxide may protect the quantum dots QD from oxygen, moisture, heat, and/or light. Accordingly, the quantum dots QD according to an embodiment may exhibit properties such as high quantum yield retention, and thus may have greater reliability.

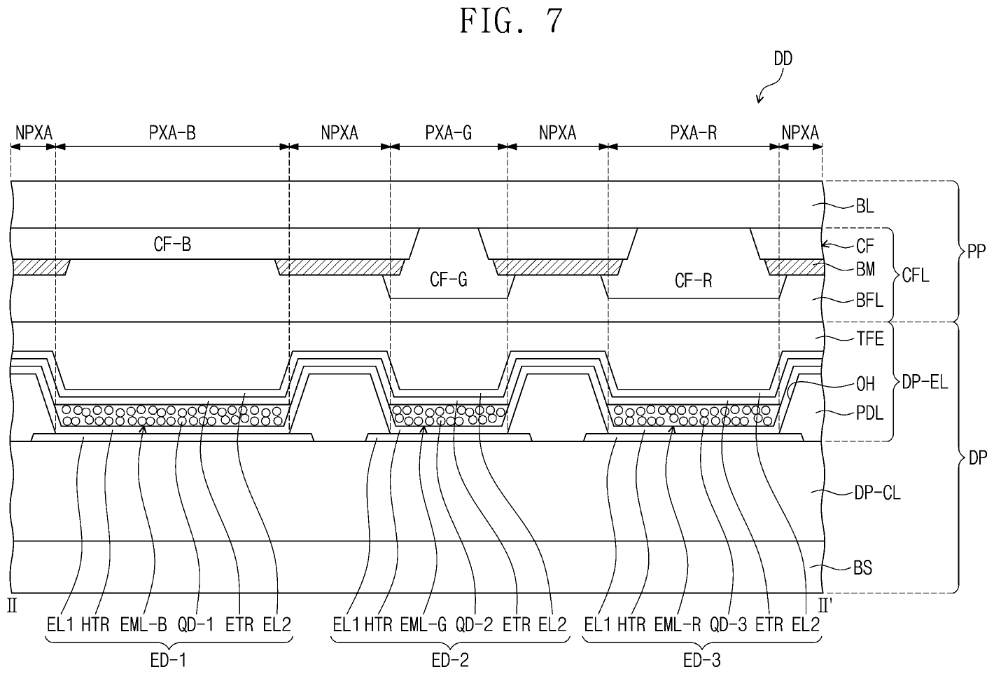

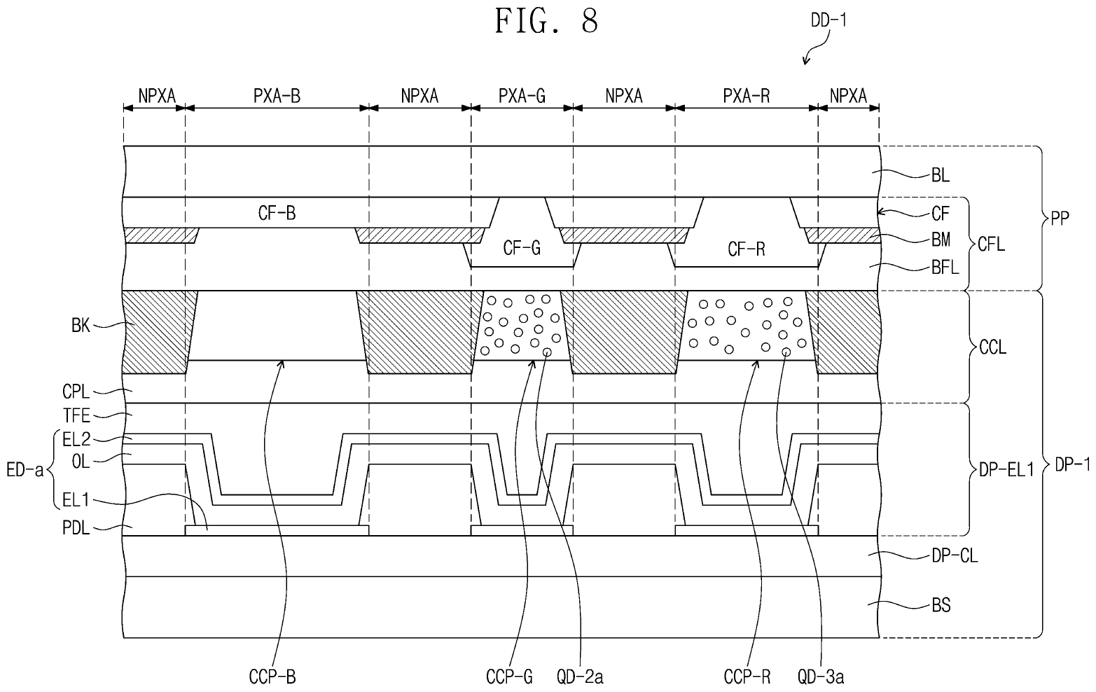

FIG. 6 is an enlarged schematic plan view showing a portion of a display device DD according to an embodiment. FIG. 7 is a schematic cross-sectional view of a display device DD according to an embodiment. FIG. 7 shows a portion corresponding to line II-II′ of FIG. 6. FIG. 8 is a schematic cross-sectional view of a display device DD-1 according to another embodiment.

Referring to FIGS. 6 to 8, the display device DD may include a non-light emitting region NPXA and light emitting regions PXA-B. PXA-G, and PXA-R. The light emitting regions PXA-B. PXA-G, and PXA-R each may be a region emitting light generated from each of light emitting elements ED-1, ED-2, and ED-3. The light emitting regions PXA-B, PXA-G, and PXA-R may be spaced apart from one another in a plan view.

The light emitting regions PXA-B, PXA-G, and PXA-R may be divided into a groups according to a color of light generated from the light emitting elements ED-1, ED-2, and ED-3. In the display device DD according to an embodiment shown in FIGS. 6 to 8, three light emitting regions PXA-B. PXA-G, and PXA-R which respectively emit blue light, green light, and red light are shown as an example. For example, the display devices DD and DD-1 according to an embodiment may include a blue light emitting region PXA-B, a green light emitting region PXA-G, and a red light emitting region PXA-R, which are distinct from one another.

Referring to FIG. 6, the blue light emitting regions PXA-B and the red light emitting regions PXA-R may be alternately arranged in the first direction DR1 to form a first group PXG1. The green light emitting regions PXA-G may be arranged in the first direction DR1 to form a second group PXG2. The first group PXG1 and the second group PXG2 may be spaced apart in the second direction DR2. Each of the first group PXG1 and the second group PXG2 may be provided in plural. The first groups PXG1 and the second groups PXG2 may be alternately arranged in the second direction DR2. One green light emitting region PXA-G may be disposed spaced apart from one blue light emitting region PXA-B or one red light emitting region PXA-R in the fourth direction DR4. The fourth direction DR4 may be a direction between the first direction DR1 and the second direction DR2. The arrangement structure of the light emitting regions PXA-B, PXA-G, and PXA-R shown in FIG. 6 may be referred to as a Pentile™ configuration.

However, embodiments are not limited thereto, and the light emitting regions PXA-R. PXA-B, and PXA-G may have various shapes, such as polygons or circles, and an arrangement structure of the light emitting regions is also not limited. For example, in an embodiment, the light emitting regions PXA-B. PXA-G, and PXA-R may have a stripe configuration in which the blue light emitting region PXA-B, the green light emitting region PXA-G, and the red light emitting region PXA-R may be alternately arranged along the first direction DR1, or may be arranged in the form of a diamond (such as Diamond Pixel™ configuration).

Referring to FIG. 7, the light emitting elements ED-1, ED-2, and ED-3 may emit light having different wavelength ranges. For example, in an embodiment, the display device DD may include a first light emitting element ED-1 emitting blue light, a second light emitting element ED-2 emitting green light, and a third light emitting element ED-3 emitting red light. However, embodiments are not limited thereto, and the first to third light emitting elements ED-1, ED-2, and ED-3 may emit light in a same wavelength range or may emit light in at least one different wavelength range.

For example, the blue light emitting region PXA-B, the green light emitting region PXA-G, and the red light emitting region PXA-R of the display device DD may respectively correspond to the first light emitting element ED-1, the second light emitting element ED-2, and the third light emitting element ED-3.

The display device DD according to an embodiment may include a light emitting clements ED-1, ED-2, and ED-3, and at least one of the light emitting elements ED-1, ED-2, or ED-3 may include emission layers EML-B, EML-G, and EML-R including quantum dots QD1, QD2, and QD3.

The display device DD according to an embodiment may include a display panel DP having light emitting elements ED-1, ED-2, and ED-3 and an optical member PP disposed on the light control layer PP. Although not shown in the drawings, the light control layer PP may be omitted from the display device DD according to an embodiment.

The display panel DP may include a base substrate BS, a circuit layer DP-CL, and a display element layer DP-EL provided on the base substrate BS, and the display element layer DP-EL may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The first emission layer EML-B of the first light emitting element ED-1 may include a first quantum dot QD1. The first quantum dot QD1 may emit blue light as first light.

The second emission layer EML-G of the second light emitting element ED-2 and the third emission layer EML-R of the third light emitting element ED-3 may respectively include a second quantum dot QD2 and a third quantum dot QD3. The second quantum dot QD2 and the third quantum dot QD3 may respectively emit green light as second light and red light as third light

At least one of the first to third quantum dots QD1, QD2, and QD3 may be a quantum dot according to an embodiment described herein. In an embodiment, the second quantum dot QD2 may be a quantum dot according to an embodiment described herein. However, embodiments are not limited thereto, and the first to third quantum dots QD1, QD2, and QD3 may each be a quantum dot as described herein.

In an embodiment, the first to third quantum dots QD1, QD2, and QD3 included in the light emitting elements ED-1, ED-2, and ED-3 may be formed of different core materials. In another embodiment, the first to third quantum dots QD1, QD2, and QD3 may be formed of a same core material, or two quantum dots selected from the first to third quantum dots QD1. QD2, and QD3 may be formed of a same core material, and the remainder may be formed of different core materials.

In an embodiment, the first to third quantum dots QD1, QD2, and QD3 may have different diameters. For example, the first quantum dot QD1 used in the first light emitting element ED-1 emitting light in a relatively short wavelength range may have a smaller average diameter than the second quantum dot QD2 of the second light emitting element ED-2 and the third quantum dot QD3 of the third light emitting element ED-3 each emitting light in a longer wavelength region.

In the description, the average diameter may be an arithmetic mean of the diameters of quantum dot particles. The diameter of the quantum dot particle may be an average value of the width of the quantum dot particle in a cross section.

The relationship of the average diameters of the first to third quantum dots QD1. QD2, and QD3 is not limited to the above limitations. For example, FIG. 7 shows that the first to third quantum dots QD1, QD2, and QD3 are similar in size from one another. However, in another embodiment, the first to third quantum dots QD1, QD2, and QD3 included in the light emitting elements ED-1, ED-2, and ED-3 may be different in size. The average diameter of two quantum dots selected from the first to third quantum dots QD1, QD2, and QD3 may be similar, and the remainder may be different.

In the display device DD according to an embodiment, as shown in FIGS. 6 and 7, an area of each of the light emitting regions PXA-B. PXA-G, and PXA-R may be different in size from one another. The area may be an area in a plan view that is defined by the first direction DR1 and the second direction DR2.

The light emitting regions PXA-B. PXA-G, and PXA-R may have different areas in size according to the color emitted from the emission layers EML-B. EML-G and EML-R of the light emitting elements ED-1, ED-2, and ED-3. For example, referring to FIGS. 6 and 7, the blue light emitting region PXA-B corresponding to the first light emitting element ED-1 emitting blue light may have a largest area, and the green light emitting region PXA-G corresponding to the second light emitting element ED-2 generating green light may have a smallest area in the display device DD according to an embodiment. However, embodiments are not limited thereto, and the light emitting regions PXA-B. PXA-G and PXA-R may emit light other than blue light, green light, and red light, or the light emitting regions PXA-B, PXA-G, and PXA-R may have a same size of area, or the light emitting regions PXA-B, PXA-G, and PXA-R may be provided at different area ratios from those shown in FIG. 6.

The light emitting regions PXA-R, PXA-G, and PXA-B may cach be a region separated by the pixel defining films PDL. The non-light emitting regions NPXA may be regions between neighboring light emitting regions PXA-B, PXA-G, and PXA-R, and may correspond to the pixel defining film PDL. In the description, the light emitting regions PXA-B, PXA-G, and PXA-R may cach correspond to a pixel. The pixel defining film PDL may separate the light emitting elements ED-1, ED-2, and ED-3. The emission layers EML-B, EML-G, and EML-R of the light emitting elements ED-1, ED-2, and ED-3 may be disposed and separated in openings OH defined by the pixel defining films PDL.

The pixel defining films PDL may be formed of a polymer resin. For example, the pixel defining films PDL may be formed including a polyacrylate-based resin or a polyimide-based resin. The pixel defining films PDL may be formed by further including an inorganic material in addition to the polymer resin. The pixel defining films PDL may be formed including a light absorbing material, or may be formed including a black pigment or a black dye. The pixel defining films PDL formed including a black pigment or a black dye may implement a black pixel defining film. When forming the pixel defining films PDL, carbon black may be used as a black pigment or a black dye, but embodiments are not limited thereto.

The pixel defining films PDL may be formed of an inorganic material. For example, the pixel defining films PDL may include silicon nitride (SiNₓ), silicon oxide (SiOₓ), silicon oxide (SiOₓN_{y}), and the like. The pixel defining film PDL may define light emitting regions PXA-B, PXA-G, and PXA-R. The light emitting regions PXA-B, PXA-G, and PXA-R, and a non-light emitting region NPXA may be separated by the pixel defining film PDL.

The light emitting elements ED-1, ED-2, and ED-3 may each include a first electrode EL1, a hole transport region HTR, emission layers EML-B, EML-G, and EML-R, an electron transport region ETR, and a second electrode EL2. In the light emitting elements ED-1, ED-2, and ED-3 included in the display device DD according to an embodiment, the quantum dots QD1, QD2, and QD3 included in the emission layers EML-B, EML-G, and EML-R may be different from each other, and the same description as provided herein with respect to FIG. 4 may be equally applied to the first electrode EL1, the hole transport region HTR, the electron transport region ETR, and the second electrode EL2. Although not shown in the drawings, the light emitting elements ED-1, ED-2, and ED-3 may each further include a capping layer between the second electrode EL2 and the encapsulation layer TFE.

The encapsulation layer TFE may cover the light emitting elements ED-1, ED-2, and ED-3. The encapsulation layer TFE may be a single layer or a laminated layer including multiple layers. The encapsulation layer TFE may be a thin film encapsulation layer. The encapsulation layer TFE protects the light emitting elements ED-1, ED-2, and ED-3. The encapsulation layer TFE may cover an upper surface of the second electrode EL2 disposed in the opening OH, and may fill the opening OH.

FIG. 7 shows that the hole transport region HTR and the electron transport region ETR may each be provided as a common layer while covering the pixel defining film PDL, but embodiments are not limited thereto. In an embodiment, the hole transport region HTR and the electron transport region ETR may cach be disposed in the opening OH defined in the pixel defining film PDL.

For example, in addition to the emission layers EML-B, EML-G, and EML-R, the hole transport region HTR and the electron transport region ETR may each be provided through inkjet printing, so that the hole transport region HTR, the emission layer EML-B, EML-G, and EML-R, and the electron transport region ETR may be correspondingly provided in the openings OH defined between the pixel defining films PDL. However, embodiments are not limited thereto, and, regardless of the method of providing cach functional layer, as shown in FIG. 7, the hole transport region HTR and the electron transport region ETR may cach be provided as a common layer while covering the pixel defining films PDL without being patterned.

In the display device DD according to an embodiment illustrated in FIG. 7, although the thicknesses of the emission layers EML-B, EML-G, and EML-R of the first to third light emitting clements ED-1, ED-2, and ED-3 are illustrated to be similar to one another, embodiments are not limited thereto. For example, in an embodiment, the thicknesses of the emission layers EML-B, EML-G, and EML-R of the first to third light emitting elements ED-1, ED-2, and ED-3 may be different from one another.

Referring to FIG. 7, the display device DD according to an embodiment may further include a light control layer PP. The light control layer PP may block external light incident to the display panel DP from the outside the display device DD. The light control layer PP may block a part of the external light. The light control layer PP may perform a reflection preventing function to minimize reflection of the external light.

In an embodiment illustrated in FIG. 7, the light control layer PP may include a color filter layer CFL. For example, the display device DD may further include the color filter layer CFL disposed on the light emitting elements ED-1, ED-2, and ED-3 of the display panel DP.

In the display device DD of an embodiment, the light control layer PP may include a base layer BL and a color filter layer CFL.

The base layer BL may provide a base surface on which the color filter layer CFL is disposed. The base layer BL may be a glass substrate, a metal substrate, a plastic substrate, and the like. However, embodiments are not limited thereto, and the base layer BL may include an inorganic layer, an organic layer, or a composite material layer.

The color filter layer CFL may include a light blocking unit BM and a color filter CF. The color filter may include filters CF-B, CF-G, and CF-R. For example, the color filter layer CFL may include a first filter CF-B transmitting a first color light, a second filter CF-G transmitting a second color light, and a third filter CF-R transmitting a third color light. For example, the first filter CF-B may be a blue filter, the second filter CF-G may be a green filter, and the third filter CF-R may be a red filter.

Each of the filters CF-B, CF-G, and CF-R may include a polymer photosensitive resin and a pigment or a dye. The first filter CF-B may include a blue pigment or a blue dye, the second filter CF-G may include a green pigment or a green dye, and the third filter CF-R may include a red pigment or a red dye.

However, embodiments are not limited thereto, and the first filter CF-B may not include a pigment or a dye. The first filter CF-B may include a polymer photosensitive resin, but not include a pigment or a dye. The first filter CF-B may be transparent. The first filter CF-B may be formed of a transparent photosensitive resin.

The light blocking unit BM may be a black matrix. The light blocking unit BM may include an organic light blocking material or an inorganic light blocking material, each including a black pigment or a black dye. The light blocking unit BM may prevent light leakage, and may separate boundaries between the adjacent filters CF-B, CF-G, and CF-R.

The color filter layer CFL may further include a buffer layer BFL. For example, the buffer layer BFL may be a protective layer protecting the filters CF-B, CF-G, and CF-R. The buffer layer BFL may be an inorganic material layer including at least one inorganic material among silicon nitride, silicon oxide, and silicon oxynitride. The buffer layer BFL may be formed of a single layer or multiple layers.

In an embodiment shown in FIG. 7, the first color filter CF-B of the color filter layer CFL is shown to overlap the second filter CF-G and the third filter CF-R, but embodiments are not limited thereto. For example, the first to third filters CF-B, CF-G, and CF-R may be separated by the light blocking unit BM and may not overlap one another. In an embodiment, each of the first to third filters CF-B, CF-G, and CF-R may be disposed to respectively correspond to the blue light emitting region PXA-B, green light emitting region PXA-G, and red light emitting region PXA-R.

Although not shown in FIG. 7, the display device DD according to an embodiment may include a polarizing layer (not shown) as a light control layer PP instead of the color filter layer CFL. The polarizing layer (not shown) may block external light provided to the display panel DP from the outside. The polarizing layer (not shown) may block a part of external light.

The polarizing layer (not shown) may reduce light that is reflected at the display panel DP from an external light. For example, the polarizing layer (not shown) may block reflected light where light provided from outside the display device DD is incident to the display panel DP. The polarizing layer (not shown) may be a circular polarizer having a reflection preventing function or the polarizing layer may include a linear polarizer and a λ/4 phase retarder. The polarizing layer (not shown) may be disposed on the base layer BL or the polarizing layer (not shown) may be disposed under the base layer BL.

Referring to FIG. 8, the display device DD-1 according to an embodiment may include a light conversion layer CCL disposed on the display panel DP-1. The display device DD-1 according to an embodiment may further include a color filter layer CFL. The color filter layer CFL may be disposed between the base layer BL and the light conversion layer CCL.

The display panel DP-1 may be a light emitting display panel. For example, the display panel DP-1 may be an organic electroluminescence display panel or a quantum dot light emitting display panel.

The display panel DP-1 may include a base substrate BS, a circuit layer DP-CL provided on the base substrate BS, and a display element layer DP-EL1.

In an embodiment, the light emitting element layer DP-EL1 may include a light emitting element ED-a, and the light emitting element ED-a may include a first electrode EL1 and a second electrode EL2 facing each other, and functional layers OL disposed between the first electrode EL1 and the second electrode EL2. The layers OL may include a hole transport region HTR (FIG. 4), an emission layer EML (FIG. 4), and an electron transport region ETR (FIG. 4). An encapsulation layer TFE may be disposed on the light emitting element ED-a.

In the light emitting element ED-a, the same description as provided with reference to FIG. 4 may be applied to the first electrode EL1, the hole transport region HTR, the electron transport region ETR, and the second electrode EL2. According to an embodiment, in the light emitting element ED-a included in the display panel DP-1, the emission layer may include a host and a dopant, which may be organic electroluminescence materials or may include the quantum dots as described herein. In the display panel DP-1 according to an embodiment, the light emitting element ED-a may emit blue light.

The light conversion layer CCL may include banks BK spaced apart from each other and light control units CCP-B, CCP-G, and CCP-R disposed between the banks BK. The banks BK may include a polymer resin and a coloring additive. The banks BK may include a light absorbing material, or may include a pigment or a dye. For example, the banks BK may include a black pigment or a black dye to implement a black bank. When forming the black bank, carbon black or the like may be used as a black pigment or a black dye, but embodiments are not limited thereto.

The light conversion layer CCL may include a first light control unit CCP-B transmitting first light, a second light control unit CCP-G including a fourth quantum dot QD2-a converting the first light into a second light, and a third light control unit CCP-R including a fifth quantum dot QD3-a converting the first light into a third light. The second light may be light of a longer wavelength range than the first light, and the third light may be light of a longer wavelength range than the first light and the second light. For example, the first light may be blue light, the second light may be green light, and the third light may be red light. The quantum dot according to an embodiment as described herein may be applied to at least one of the quantum dots QD2-a and QD3-a included in the light control units CCP-B, CCP-G, and CCP-R. For example, the quantum dot according to an embodiment as described herein may be applied to the fourth quantum dot QD2-a to convert the first light into the second light.

The light conversion layer CCL may further include a capping layer CPL. The capping layer CPL may be disposed above the light control units CCP-B, CCP-G, and CCP-R, and the banks BK. The capping layer CPL may prevent penetration of moisture and/or oxygen (hereinafter, referred to as “moisture/oxygen”). The capping layer may be disposed on the light control units CCP-B, CCP-G, and CCP-R to prevent the light control units CCP-B, CCP-G, and CCP-R from being exposed to moisture/oxygen. The capping layer CPL may include at least one inorganic layer.

The display device DD-1 according to an embodiment may include a color filter layer CFL disposed on the light conversion layer CCL, and the descriptions of FIG. 7 may be equally applied to the color filter layer CFL and the base layer BL.

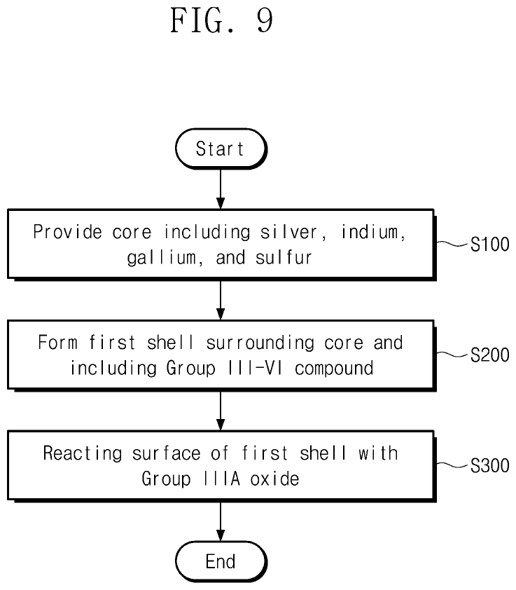

FIG. 9 is a flowchart showing a method for preparing a quantum dot according to an embodiment.

Referring to FIG. 9, a method for preparing a quantum dot includes providing a core including silver, indium, gallium, and sulfur (S100), forming a first shell surrounding the core and including a Group III-VI compound (S200), and reacting a surface of the first shell with a Group IIIA oxide (S300). The method for preparing a quantum dot according to an embodiment may further include surface-treating the surface of the first shell with a first solvent, before the step of reacting the surface of the first shell with the Group IIIA oxide.

In the method for preparing a quantum dot according to an embodiment, forming a core containing silver, indium, gallium, and sulfur may be performed first. As a starting material for forming the core, a first mixture including a first precursor material containing a silver precursor, an indium precursor, and a gallium precursor, and a second solvent may be used. A first precursor material including a silver precursor, an indium precursor, a gallium precursor, and a sulfur precursor may be dispersed in the second solvent to provide the first mixture. The second solvent may be a material that coordinates a surface of the core to be prepared later and may improve the dispersibility of the core. The second solvent may dissolve the first precursor material. The second solvent may include oleylamine, trioctylphosphine oxide, and trioctylamine.

Dissolving the first precursor material in an auxiliary solvent may be performed before the dispersing of the first precursor material in the second solvent, but embodiments are not limited thereto. When the first precursor material is dissolved in an auxiliary solvent, the auxiliary solvent may include at least one of hexane, toluene, chloroform, dimethyl sulfoxide, cyclohexylbenzene, hexadecane, or dimethyl formamide. However, the embodiments are not limited thereto.

The silver precursor may be at least one selected from the group consisting of silver halide, silver acetate, and silver nitrate. For example, the silver precursor may be silver iodide (AgI). However, embodiments are not limited thereto.

The gallium precursor may be at least one selected from gallium nitride, gallium phosphide, gallium(III) chloride, gallium(III) acetylacetonate, gallium(III) bromide, gallium(III) chloride, gallium(III) fluoride, gallium(III) iodide, gallium(III) nitrate hydrate, gallium(III) sulfate, and gallium(III) sulfate hydrate. For example, the gallium precursor may be gallium iodide.

The indium precursor may be at least one selected from the group consisting of indium(III) acetylacetonate, indium(III) chloride, indium(III) iodide, indium(III) acetate, trimethyl indium, alkyl indium, aryl indium, indium(III) myristate, indium(III) myristate acetate, and indium(III) myristate 2 acetate. For example, the indium precursor may be indium iodide.

A sulfur precursor may be added to the first mixture to form a core. The forming of the core may include heat-treating after the adding of the sulfur precursor to the first mixture. For example, the heat-treatment may be performed at a temperature equal to or greater than about 240° C. after the adding of the sulfur precursor to the first mixture. The forming of the core may include reacting the silver precursor, the indium precursor, and the gallium precursor included in the first mixture with the sulfur precursor. The silver precursor, the indium precursor, and the gallium precursor included in the first mixture may react with the sulfur precursor to form a core CO (FIG. 5).

The sulfur precursor may be at least one selected from the group consisting of trioctylphosphine-sulfide (TOP-S), tributylphosphine sulphide, triphenylphosphine sulfide, S-oleylamine (Sulfur-Oleylamine), element sulfur, octanethio, dodecanethiol, octadecanethiol, a-toluenethiol, allyl mercaptan, and bis(trimethylsilyl) sulfide.

The method for preparing a quantum dot according to an embodiment may further include purifying the prepared core after the forming of the core. The purification may be performed using chloroform, ethanol, acetone, or any combination thereof. However, embodiments are not limited thereto, and the purifying of the core in the method for preparing a quantum dot may be omitted depending on process conditions and the like.

After the providing of a core (S100), forming a first shell (S200) may be performed. The forming of the first shell may include reacting the core with a Group III precursor and a Group VI precursor. For example, the forming of the first shell may include adding a second precursor material including a Group III precursor and a Group VI precursor to a solution containing the core. After the adding of the second precursor material to a solution in which the purified core is dispersed in a solvent, the mixture may be subjected to a reaction at a temperature equal to or greater than about 240° C. Accordingly, the Group III precursor and the Group VI precursor may be subjected to a reaction to form a first shell surrounding the core. The core prepared herein and the first shell surrounding the core may be collectively referred to as first particles.

The Group III precursor may be at least one selected from the group consisting of aluminum phosphate, aluminum acetylacetonate, aluminum chloride, aluminum fluoride, aluminum oxide, aluminum nitrate, aluminum sulfate, gallium nitride, gallium phosphide, gallium chloride, gallium acetylacetonate, gallium bromide, gallium chloride, gallium fluoride, gallium iodide, gallium nitrate hydrate, gallium sulfate, and gallium sulfate hydrate. However, embodiments are not limited thereto. In an embodiment, the Group III precursor may include gallium.

The Group VI precursor may be at least one selected from the group consisting of sulfur, trioctylphosphine-sulfide (TOP-S), tributylphosphine sulphide, triphenylphosphine sulfide, S-oleylamine (sulfur-oleylamine), elemental sulfur, octanethio, dodecanethiol, octadecanethiol, α-toluenethiol, allyl mercaptan, bis(trimethylsilyl) sulfide, selenium, trialkylphosphine selenide, trialkenylphosphine selenide, alkylamino selenide, alkenylamino selenide, trialkylphosphine telluride, trialkenylphosphine telluride, alkylamino telluride, and alkenylamino telluride. However, embodiments are not limited thereto. In an embodiment, the Group VI precursor may include sulfur.

The method for preparing a quantum dot according to an embodiment may further include purifying the first particles including the core and the first shell surrounding the core after the forming of the first shell. The purification may be performed using chloroform, ethanol, acetone, or any combination thereof. However, embodiments are not limited thereto, and the purifying of the first particles in the method for preparing a quantum dot may be omitted depending on process conditions and the like.

After the forming of the first shell (S200), reacting a surface of the first shell with a Group IIIA oxide may be performed. After the forming of the first shell, reacting the first particles including the core and the first shell with a Group IIIA oxide may be performed. The step of reacting the surface of the first shell with the Group IIIA oxide may include doping the first shell with a Group IIIA element included in the Group IIIA oxide. The Group IIIA oxide may be injected into a solution containing the first particles for doping. In an embodiment, the Group IIIA oxide may be aluminum isopropoxide. However, the Group IIIA oxide is not limited thereto.

In an embodiment, the first shell may be doped with the Group IIIA oxide through a cation exchange reaction. For example, the first shell may be doped with the Group IIIA elements of the Group IIIA oxide through a cation exchange reaction with at least one of the Group III elements included in the first shell. The Group IIIA elements of the Group IIIA oxide may be applied for doping at a position of the Group III elements in the first shell participating in the cation exchange reaction.

The method for preparing a quantum dot according to an embodiment may further include surface-treating the surface of the first shell with a first solvent, before the step of reacting the surface of the first shell with the Group IIIA oxide. The first solvent may be a material that coordinates the surface of the first particles and improves the dispersibility of the first particles. The first solvent may dissolve the first particles. The first solvent may improve the dispersibility of the first particles.

The surface-treating of the surface of the first shell with the first solvent may include dissolving the first particles including the core and the first shell in the first solvent and heat-treating the resulting product. For example, second particles may be dissolved in the first solvent, and heat-treated at a temperature equal to or greater than about 180° C. In an embodiment, the first solvent may include at least one of oleylamine, trioctylphosphine, trioctylphosphine oxide, or trioctylamine. For example, the first solvent may be trioctylphosphine. However, embodiments are not limited to thereto, and the surface-treating of the surface of the first shell with the first solvent may be omitted.

The method for preparing a quantum dot according to an embodiment may further include reacting the surface of the first shell with the Group III precursor and the Group VI precursor. In an embodiment, the step of reacting the surface of the first shell with the Group IIIA precursor and the step of reacting the surface of the first shell with the Group III precursor and the group VI precursor may be performed in a same process. For example, the Group III precursor, the Group VI precursor, and the Group IIIA oxide may be added to a solution containing the first particles, and heat-treated at a temperature equal to or greater than about 200° C.

In the step of reacting the surface of the first shell with the Group III precursor, the Group VI precursor, and the Group IIIA oxide, a second shell including the Group III-VI compounds and the Group IIIA oxide may be formed on the surface of the first shell. For example, the surface of the first shell may react with the Group IIIA oxide, the Group III precursor, and the Group VI precursor to form the second shell SH2 (FIG. 5) surrounding the first shell SH1 (FIG. 5). For example, the Group III elements and the Group VI elements grow on the surface of the first shell to form a Group III-VI compound layer having a certain thickness. The surface of the formed III-VI compound layer may be doped with the Group IIIA oxide. The doped Group III-VI compound layer may correspond to the second shell SH2 shown in FIG. 5.

The doped Group III-VI compound layer may include a first layer and a second layer. The first layer may be adjacent to the first shell. The first layer may enclose the first shell. The second layer may be spaced apart from the first shell. The second layer may be spaced apart from the first shell with the first layer therebetween. The second layer may include a Group IIIA oxide having a higher concentration than the first layer. However, embodiments are not limited to thereto, and the Group IIIA oxide may be uniformly distributed in the doped Group III-VI compound layer.

The Group IIIA oxide may have a structure in which an alkoxy group is bonded to the Group IIIA elements. The Group IIIA oxide may include the Group IIIA elements and include first to third alkoxy groups linked to the Group IIIA elements. In an embodiment, the Group IIIA oxide may be represented by Formula 1.

M(OR)₃ [Formula 1]

In Formula 1, M may be aluminum, indium, or thallium. In an embodiment, M may be aluminum.

In Formula 1, R may be a substituted or unsubstituted alkyl group having 1 to 20 carbon atoms. In an embodiment, R may be a substituted or unsubstituted alkyl group having 1 to 10 carbon atoms. For example, R may be a substituted or unsubstituted isopropyl group.

In an embodiment, the Group IIIA oxide may be provided onto the surface of the first shell in a thiolated form. For example, at least one of the first to third alkoxy groups included in the Group IIIA oxide may be substituted with a thiol group. For example, the Group IIIA oxide may include the Group IIIA elements, and may include a first alkoxy group, a second alkoxy group, and a thiol group linked to the Group IIIA elements. The thiolated Group IIIA oxide may be formed by reacting the Group IIIA oxide with a thiol-based compound. The thiol-based compound may be, for example, 1-dodecanethiol, but is not limited thereto.

In an embodiment, the thiolated Group IIIA oxide may be represented by Formula 2.

M(OR)₃₋ₙ(SR′)ₙ [Formula 2]

In Formula 2, R′ may be a substituted or unsubstituted alkyl group having 1 to 20 carbon atoms. For example, R′ may be a substituted or unsubstituted dodecyl group.

In Formula 2, n may be an integer from 0 to 3.

In Formula 2, M and R are the same as described in Formula 1.

The method for preparing a quantum dot QD according to an embodiment may further include ashing the prepared quantum dot QD after the forming of the second shell. The mixture in which the quantum dot is formed may be cooled to room temperature, purified, and redispersed to prepare quantum dots having high purity. The purification and redispersion may further include adding a nonsolvent to the mixture in which the quantum dots are formed to separating the quantum dots. The non-solvent may be a polar solvent that is miscible with an organic solvent used in the reaction but not capable of dispersing the quantum dots.

The non-solvent may be determined depending on the organic solvent used in the reaction, and may be at least one selected from the group consisting of acetone, ethanol, butanol, isopropanol, ethanediol, tetrahydrofuran, dimethylsulfoxide, diethyl ether, formaldehyde, acetaldehyde, and ethylene glycol. However, embodiments are not limited thereto.

Centrifugation, precipitation, chromatography, or distillation may be used to separate the quantum dots. The separated quantum dots may be added to a washing solvent as needed and washed. The solvent for washing is not particularly limited, and hexane, heptane, octane, chloroform, toluene, benzene, and the like may be used.

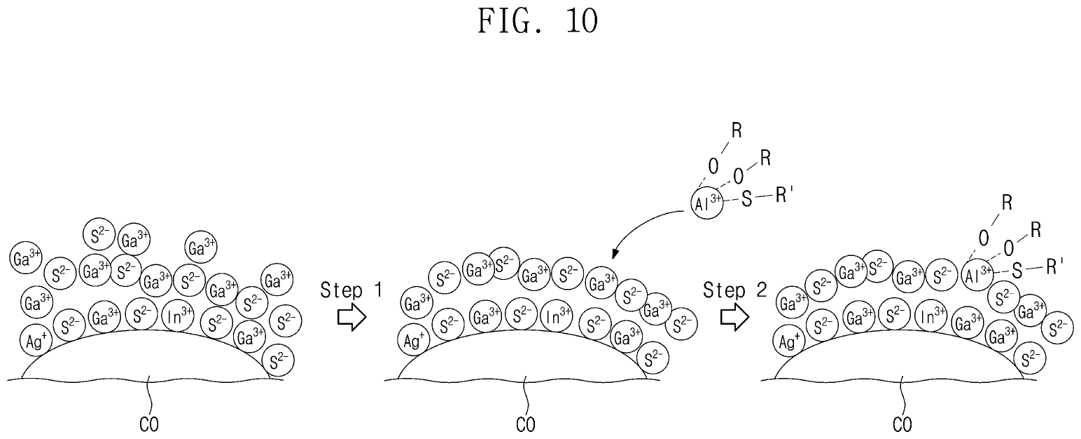

FIG. 10 is a schematic view of a process in a method for preparing a quantum dot according to an embodiment. FIG. 10 shows reacting the surface of the first shell with the Group IIIA oxide in the method for preparing a quantum dot according to an embodiment as an example.

In FIG. 10, “Step 1” indicates forming the first shell. In FIG. 10, “Step 2” indicates reacting the surface of the first shell with the Group IIIA oxide.

Referring to Step 1, the core CO may be provided. The core CO may include silver, indium, gallium, and sulfur. The core CO may include Group I-III-VI compounds formed by silver cations, indium cations, gallium cations, and sulfur anions.

In order to form the first shell, the core CO may react with the Group III precursor and the Group VI precursor. The step of reacting the core CO with the Group III precursor and the Group VI precursor may be growing the Group III elements and the Group VI elements on the surface of the core CO. The Group III elements and the Group VI elements may be derived from the Group III precursors and the Group VI precursors, respectively. In FIG. 10, for convenience of description, the Group III element is Ga and the Group VI element is S, but embodiments are not limited thereto.

When the reaction between the core CO, the Group III precursor and the Group VI precursor is completed, a first shell having a thickness (e.g., a predetermined or a selectable thickness) may be formed from the surface of the core CO. The first shell may include Group III-VI compounds formed by cations of the Group III elements and anions of the Group VI elements. The first shell may serve as a buffer layer that surrounds and protects the core CO. The first shell may prevent cations included in the core CO from reacting with the Group IIIA oxide to be substituted with the Group IIIA elements in the step of reacting with the Group IIIA oxide, which will be described later.

Referring to Step 2, a step of reacting the surface of the first shell containing the Group III-VI compounds with the Group IIIA oxide may be performed. The step of reacting the surface of the first shell with the Group IIIA oxide may include doping at least one of the Group III elements included in the first shell with the Group IIIA element of the Group IIIA oxide. The doping of the Group IIIA elements may be performed through a cation exchange method. For example, at least one of the Group III elements included in the first shell may be substituted with the Group IIIA element of the Group IIIA oxide. For example, as shown in FIG. 10, an Al element of the Group IIIA oxide may be doped in place of a Ga element included in the first shell through a cation exchange reaction. In FIG. 10, the thiolated Group IIIA oxide represented by Formula 2 above is shown as an example, but embodiments are not limited thereto.

Hereinafter, with reference to Examples and Comparative Examples, quantum dots according to embodiments will be described. The Examples shown below are shown only for the understanding of embodiments, and the scope of the disclosure is not limited thereto.

### EXAMPLES

### Synthesis of Example

### Step 1: Synthesis of AgInGaS core

0.4 mmol of AgI, 0.5 mmol of GaI₃, and 0.4 mmol of InI₃ were mixed with oleylamine, trioctylphosphine oxide (TOA), and trioctylamine (TOA) in a three-neck flask, and the mixture was degassed and stirred at 120° C.for 30 minutes to remove oxygen and moisture inside, thereby forming a reaction solution. 1.6 mmol of sulfur-oleylamine was added to the reaction solution in a N₂ atmosphere, and the mixture was heated to 240° C., kept for a period of time, and cooled to 200° C., and TOP (trioctylphosphine) was injected thereto, and the mixture was subjected to a reaction for a period of time to synthesize an AgInGaS core.

### Step 2: Synthesis of AgInGaS/GaS

2.27 mmol of GaCl₃ and 1.6 mmol of sulfur-oleylamine were mixed with the AgInGaS core and the mixture was subjected to a reaction at 240° C.for a period of time. After the resulting produce was cooled to 200° C. TOP was injected and was subjected to a reaction to form a GaS shell on a surface of the AgInGaS core to synthesize AgInGaS/GaS quantum dots (hereinafter, first particles).

### Step 3: Synthesis of AgInGaS/GaS/GaS:Al

A mixture of 1.4 mmol of and 1.4 mmol of DDT (1-dodecanethiol) was mixed with the first particle, and subjected to a reaction at a temperature equal to or greater than about 200° C. to form a GaS:Al layer on a surface of the GaS shell.

### Synthesis of Comparative Example 1

AgInGaS/GaS quantum dots were synthesized through the same method as in the synthesis of Example, except that step 3 was omitted.

### Synthesis of Comparative Example 2

A solution of 2.27 mmol of GaCl₃, 1.6 mmol of sulfur-oleylamine, 1.4 mmol of Al(O-i-pr)₃, and 1.4 mmol of DDT (1-dodecanethiol) was mixed with the AgInGaS core formed in step 1, and subjected to a reaction at 240° C.to form a GaS:Al layer on a surface of the AgInGaS core.

Tables 1 and 2 show a comparison of the ICP component ratio, emission wavelength, quantum yield, and quantum yield retention of quantum dots according to the Example and Comparative Examples. The ICP component ratio indicates the ratio of the number of atoms of Group IIIA elements included in the quantum dots to the number of anions included in the quantum dots of the prepared Example and Comparative Examples. The quantum yield was determined using QE-2100, and ICP analysis was determined using Nexion 2000, and the results are shown in Tables 1 and 2.

In Table 2, irradiation of 450 nm excitation light was applied for 2 hours with a light amount of 60 mW/cm² for the quantum dots prepared in the Example and Comparative Examples, and the quantum yield was determined to calculate the quantum yield retention after 1 hour and 2 hours compared to an initial measurement value. In Table 2, the quantum yield retention (%) is a value obtained by determining the quantum yield before irradiating the quantum dots with excitation light (initial quantum yield) and converting the degree to which the initial quantum yield is maintained into %. The quantum yield retention may be calculated through Equation C:

Quantum yield retention 1=(QY₂/QY₁)×100 [Equation C]

In Equation C, QY₁ is a quantum yield value measured before irradiating the quantum dots with excitation light, and QY₂ is a quantum yield value measured after irradiating the quantum dots with excitation light of 450 nm at a light amount of 60 mW/cm² for 1 hour or 2 hours.

TABLE 1

| | ICP component | PL | |
|---|---|---|---|
| | ratio | wavelength | PL QY |
| Item | (Al/S) | (nm) | (%) |
| Example | 0.101 | 533 | 74.3 |
| Comparative Example 1 | 0 | 530 | 77.4 |
| Comparative Example 2 | 0.267 | 540 | 49.3 |

TABLE 2

| | PL QY (%) | | | PL QY retention (%) | | |
|---|---|---|---|---|---|---|
| | | Compar- | Compar- | | Compar- | Compar- |
| | | ative | ative | | ative | ative |
| Time | Exam- | Exam- | Exam- | Exam- | Exam- | Exam- |
| (hr) | ple | ple 1 | ple 2 | ple | ple 1 | ple 2 |
| 0 | 74.3 | 77.4 | 49.3 | 100 | 100 | 100 |
| 1 | 46.9 | 36.2 | 30 | 63 | 47 | 61 |
| 2 | 10.3 | 6.8 | 2.8 | 14 | 9 | 6 |

Referring to the results of Tables 1 and 2, it may be seen that Examples prepared through the method for preparing quantum dots according to an embodiment have both greater quantum yield and greater quantum yield retention than Comparative Examples.

Comparing the Example and Comparative Example 1, the quantum dots of the Example corresponds to quantum dots having an AgInGaS/GaS/GaS:Al structure, and the quantum dots of Comparative Example 1 correspond to quantum dots having an AgInGaS/GaS structure. The quantum dots of Comparative Example 1 have the same structure as the quantum dots of the Example, except that a GaS shell doped with Al is not included. The quantum dots of Comparative Example 1 may be first particles in a state prior to reacting the first shell with the Group IIIA oxide in the method for preparing quantum dots according to an embodiment.

It may be seen that the initial quantum yields of the Example and Comparative Example 1 are 74.3% and 77.4%, respectively, showing similar values. However, Comparative Example 1 has a quantum yield retention of 47% and 9% after light irradiation for 1 hour and 2 hours respectively, whereas the Example has a greater quantum yield retention of 63% and 14% after light irradiation for 1 hour and 2 hours, respectively. For example, it may be seen that the quantum dots formed through the method for preparing quantum dots of the Example exhibit a high initial quantum yield similar to that of the quantum dots of Comparative Example 1 that are not doped with the Group IIIA oxide, but exhibit higher quantum yield retention than Comparative Example 1. For example, in the quantum dots of the Example, the quantum dots QD may be effectively protected by including a shell doped with the Group IIIA oxide, and thus, exhibit a higher level of stability than the quantum dots of Comparative Example 1 that are not doped with the Group IIIA oxide.

Comparing the Example and Comparative Example 2, it may be seen that Comparative Example 2 has an initial quantum yield of 49.3%, whereas Example has an initial quantum yield of 74.3%, which is significantly higher. Comparative Example 2 has a quantum yield retention of 61% and 6% after light irradiation for 1 hour and 2 hours, respectively, whereas the Example has a greater quantum yield retention of 63% and 14% after light irradiation for 1 hour and 2 hours, respectively. For example, it may be seen that the quantum dots formed through the method for preparing quantum dots of the Example exhibit a higher initial quantum yield than the quantum dots of Comparative Example 2, and also exhibit high quantum yield retention.

Compared to the quantum dots of the Example, the quantum dots of Comparative Example 2 correspond to those in which forming the first shell is omitted and the GaS:Al shell layer is formed directly on the core. When reacting the Group IIIA oxide with the core surface, silver, indium, or gallium included in the core may be substituted with Group IIIA elements of the Group IIIA oxide through a cation exchange reaction. When silver, indium, or gallium included in the core rather than Group III elements included in the shell is substituted with Group IIIA elements, the efficiency and stability of the quantum dots QD may be reduced. In the case of the Example, silver, indium, or gallium included in the core may be prevented from being substituted with the Group IIIA elements of the group IIIA oxide by first forming a first shell containing III-VI compounds on the surface of the core and forming a GaS:Al shell layer.

The quantum dots of the Example exhibit high quantum yield retention to have high stability, and thus provide improved light emitting properties. Therefore, the quantum dots of the Example may exhibit higher light emitting efficiency than the quantum dots of Comparative Examples 1 and 2.

AgInGaS quantum dots, which are I-III-VI semiconductor compounds, may exhibit defect emission due to recombination of charges at defect levels within the band gap. I-III-VI quaternary semiconductor compounds such as AgInGaS quantum dots have various defects due to the increased degree of freedom, which is caused by the inclusion of three cations. For this reason, a method for reducing defect emission by introducing a GaS shell surrounding the AgInGaS core may be used, but the quantum dots containing an AgInGaS core/GaS shell structure have low chemical stability due to the amorphous shape of the GaS shell.

According to an embodiment, quantum dots may include a core containing Ag, In, Ga, and S, and a shell surrounding the core and containing Group III-VI compounds, and the shell has a structure doped with the Group IIIA oxide, thereby exhibiting high quantum yield, and high quantum yield retention. A method for preparing quantum dots according to an embodiment of the inventive concept includes reacting a surface of a first shell with a Group IIIA oxide after forming the first shell containing Group III-VI compounds on a surface of a core to ensure the stability of quantum dots, and as the first shell serves as a buffer shell protecting the core, in the process of doping with the Group IIIA oxide, the Group IIIA oxide may be prevented from reacting with cations included in the core. Therefore, when the quantum dots prepared through the method for preparing quantum dots of an embodiment are applied to a display device, excellent light efficiency and reliability may be obtained.

A quantum dot of an embodiment of the inventive concept includes a shell doped with a Group IIIA oxide, and may thus exhibit high quantum yield and excellent stability. A method for preparing a quantum dot of an embodiment of the inventive concept may provide a quantum dot exhibiting high quantum yield and excellent stability.

A display device of an embodiment of the inventive concept includes a quantum dot exhibiting high quantum yield and excellent stability, and may thus exhibit improved light emitting luminous efficiency.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A quantum dot comprising:
a core including silver, indium, gallium, and sulfur; and
a shell surrounding the core, the shell including a Group III-VI compound, wherein the shell is doped with a Group IIIA oxide.

2. The quantum dot of claim 1, wherein the Group III-VI compound is GaS.

3. The quantum dot of claim 1, wherein
the shell comprises:
a first shell surrounding the core; and
a second shell surrounding the first shell,
the first shell and the second shell each include the Group III-VI compound, and
at least one of the first shell or the second shell is doped with the Group IIIA oxide.

4. The quantum dot of claim 3, wherein the second shell is doped with the Group IIIA oxide.

5. The quantum dot of claim 3, wherein
the first shell comprises GaS, and
the second shell comprises the GaS and the Group IIIA oxide.

6. The quantum dot of claim 1, wherein the Group IIIA oxide comprises aluminum oxide.

7. The quantum dot of claim 1, wherein a molar ratio of the Group IIIA element of the Group IIIA oxide included in the quantum dot to sulfur included in the quantum dot is in a range of about 0.001 to about 0.25.

8. The quantum dot of claim 1, wherein the shell has a thickness of in a range of about 0.01 nm to about 10 nm.

9. The quantum dot of claim 1, wherein the Group IIIA oxide is disposed on a surface of the shell.

10. The quantum dot of claim 1, wherein the quantum dot has a central emission wavelength in a range of about 510 nm to about 540 nm.

11. A method for preparing a quantum dot, the method comprising:
providing a core including silver, indium, gallium, and sulfur;
forming a first shell surrounding the core and including a Group III-VI compound; and
reacting a surface of the first shell with a Group IIIA oxide.

12. The method of claim 11, wherein the forming of the first shell comprises reacting the core with a Group III precursor and a Group VI precursor.

13. The method of claim 11, further comprising:
reacting the surface of the first shell with a Group III precursor and a Group VI precursor, wherein
the step of reacting the surface of the first shell with the Group IIIA oxide and the step of reacting the surface of the first shell with the Group III precursor and the Group VI precursor are performed in a same process.

14. The method of claim 13, wherein the surface of the first shell reacts with the Group IIIA oxide, the Group III precursor, and the Group VI precursor to form a second shell surrounding the first shell.

15. The method of claim 11, wherein the Group IIIA oxide is represented by Formula 1 or Formula 2:
M(OR)₃ [Formula 1]
M(OR)₃₋ₙ(SR′)ₙ [Formula 2]
wherein in Formulas 1 and 2,
M is aluminum, indium, or thallium,
R and R′are each independently a substituted or unsubstituted alkyl group having 1 to 20 carbon atoms, and
n is an integer from 0 to 3.

16. The method of claim 11, wherein the Group IIIA oxide is aluminum isopropoxide.

17. The method of claim 11, further comprising:
surface-treating the surface of the first shell with a first solvent, before the step of reacting the surface of the first shell with the Group IIIA oxide.

18. A display device comprising:
a display panel; and
a light conversion layer disposed on the display panel and including a plurality of light control units, wherein
at least one of the light control units includes a quantum dot that includes:
a core containing silver, indium, gallium, and sulfur; and
a shell surrounding the core, the shell containing a Group III-VI compound, and the shell is doped with a Group IIIA oxide.

19. The display device of claim 18, wherein
the display panel comprises a light emitting element generating a first light, and
the light conversion layer comprises:
a first light control unit transmitting the first light;
a second light control unit converting the first light into a second light; and
a third light control unit converting the first light into a third light.

20. The display device of claim 18, wherein
the shell comprises:
a first shell surrounding the core; and
a second shell surrounding the first shell, wherein
the first shell and the second shell each include the Group II-VI compound, and
at least one of the first shell or the second shell is doped with the Group IIIA oxide.
